(19) United States
(12) Patent Application Publication
(10) Pub. No.: US 2019/0115806 A1
(43) Pub. Date: Apr. 18, 2019

(54) MOTOR

(71) Applicant: NIDEC CORPORATION, Minami-ku Kyoto (JP)

(72) Inventors: Yoshiaki YAMASHITA, Minami-ku Kyoto (JP); Takashi HATTORI, Minami-ku Kyoto (JP); Takahiro KIZU, Minami-ku Kyoto (JP)

(21) Appl. No.: 16/090,363

(22) PCT Filed: Mar. 21, 2017
(86) PCT No.: PCT/JP2017/011282

§ 371 Date: Oct. 1, 2018

(30) Foreign Application Priority Data
Mar. 31, 2016 (JP) 2016-071702

(51) Int. Cl. H02K 9/22; H02K 5/16; H02K 5/22; H02K 7/08; H02K 11/21; H02K 11/33; H05K 1/02

(52) U.S. Cl. CPC H02K 9/22; H02K 5/161; H02K 5/225; H02K 7/083; H02K 11/21; H05K 2201/066; H05K 1/0203; H02K 2211/03; H05K 2201/10409; H05K 2201/10166; H02K 11/33

(57) ABSTRACT

A motor may include a rotor having a rotating shaft extending in an up-down direction, a stator that opposes the rotor, a housing that holds the stator, a heat sink that is attached to the housing, and a circuit board on which electronic components are mounted and which is disposed on a lower surface of the heat sink. The electronic components may include a heat-generating element. The housing may include a cylindrical portion and a flange portion extending outward in a radial direction from an upper end of the cylindrical portion. The heat sink may have a protruding portion protruding downward in an axial direction and is attached to an upper surface of the flange portion in the axial direction using a fixing member. The heat-generating element may be in contact with the heat sink via a heat-conducting member.

This is the U.S. national stage of application No. PCT/JP2017/011282, filed on Mar. 21, 2017, and priority under 35 U.S.C. § 119(a) and 35 U.S.C. § 365(b) is claimed from Japanese Application No. 2016-071702, filed Mar. 31, 2016; the disclosures of which are incorporated herein by reference.

### FIELD OF THE INVENTION

The present disclosure relates to a motor.

### BACKGROUND

To date, a motor has a rotor, a stator, and a control unit on which a circuit board and the like are mounted. When electric power is supplied from an external power source or the like to the stator via the control unit, the rotor can rotate relative to the stator.

Various elements, wiring, and the like are arranged on the circuit board. When an electric current flows from an external power supply or the like to the circuit board, the elements, wiring, and the like on the circuit board generate heat. Such heat generation may not only destroy the elements but may also deform the circuit board and the like. For this reason, it is necessary to take measures such as to dissipate heat generated from the elements and the like to the outside of the motor.

However, in the related art motor, therefore, the dimension in the axial direction of the rotation axis of the rotor increases. In addition, the number of portions of the motor increases. Therefore, the number of assembly steps and the manufacturing cost increase.

In view of the above circumstances, the present disclosure aims to provide a motor that has a reduced dimension in the axial direction and that has a heat dissipation structure that can be easily assembled.

### SUMMARY

In order to achieve the above, an exemplary motor of the present disclosure includes a rotor having a rotating shaft extending in an up-down direction, a stator that opposes the rotor, a housing that holds the stator, a heat sink that is attached to the housing, and a circuit board on which electronic components are mounted and which is disposed on a lower surface of the heat sink. The electronic components include a heat-generating element. The housing includes a cylindrical portion and a flange portion extending outward in a radial direction from an upper end of the cylindrical portion. The heat sink has a protruding portion protruding downward in an axial direction and is attached to an upper surface of the flange portion in the axial direction using a fixing member. The heat-generating element is in contact with the heat sink via a heat-conducting member.

The above and other elements, features, steps, characteristics and advantages of the present disclosure will become more apparent from the following detailed description of the embodiments with reference to the attached drawings.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a schematic longitudinal sectional view illustrating an example of a structure of a motor according to a first embodiment of the present disclosure.

FIG. 2 is a bottom view of a heat sink according to the first embodiment of the present disclosure.

FIG. 3 is a schematic longitudinal sectional view illustrating an example of a structure between a heat sink and a circuit board according to a modification example of the first embodiment of the present disclosure.

FIG. 4 is a schematic longitudinal sectional view illustrating an example of a structure of the motor according to a second embodiment of the present disclosure.

FIG. 5 is a top view of a housing according to a third embodiment of the present disclosure.

FIG. 6 is a cross-sectional view illustrating an example of a structure for fixing an upper lid portion to a cylindrical portion in the third embodiment of the present disclosure.

FIG. 7 is a cross-sectional view illustrating another example of a structure for fixing the upper lid portion to the cylindrical portion in the third embodiment of the present disclosure.

### DETAILED DESCRIPTION

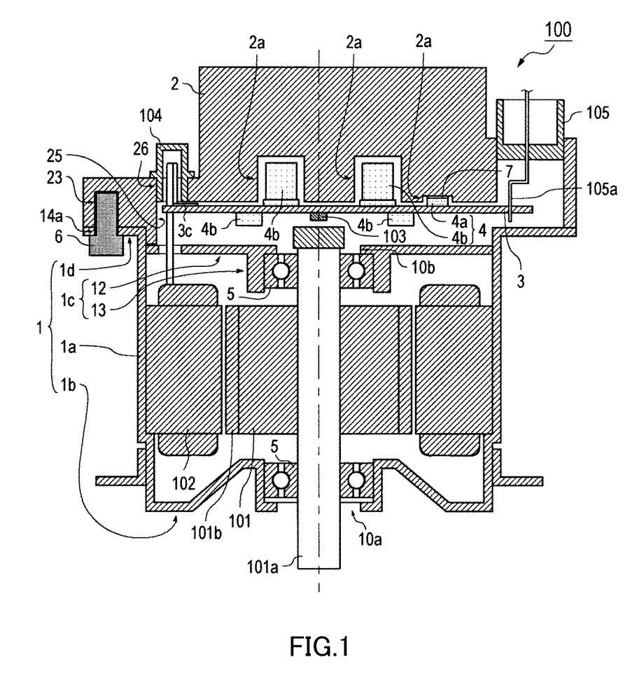

Exemplary embodiments of the present disclosure will be described below with reference to the drawings. Further, in the present specification, the direction in which a rotating shaft of a rotor 101 (refer to a shaft 101a in FIG. 1 to be described later) extends is simply referred to as the “axial direction”. Furthermore, in the axial direction, the direction from the shaft 101a to a heat sink 2 is simply referred to as “upward” in the axial direction, and the direction from the heat sink 2 to the shaft 101a is simply referred to as “downward” in the axial direction. The radial direction from and the circumferential direction around the shaft 101a are simply referred to as “radial direction” and “circumferential direction”, respectively. On the surface of each constituent element, a surface facing upward in the axial direction is called “upper surface”, a surface facing downward in the axial direction is called “lower surface”, and a surface facing in the radial direction is called “side surface”.

First, a motor 100 according to an exemplary first embodiment of the present disclosure will be described. FIG. 1 is a schematic longitudinal sectional view illustrating an example of structure of the motor 100 according to a first embodiment of the present disclosure. FIG. 1 illustrates a cross section in the case where the motor 100 is cut along a cutting plane including the rotation axis of the rotor 101. The motor 100 in FIG. 1 is a motor mounted on a vehicle or the like.

The motor 100 includes the rotor 101, a stator 102, which has an annular shape, a housing 1, the heat sink 2, a circuit board 3 on which electronic components 4 are mounted, bearings 5, a cover 104, and a connector 105.

The rotor 101 has the shaft 101a and a plurality of magnets 101b. The shaft 101a is a rotating shaft extending in the up-down direction in the axial direction. The stator 102 is an armature of the motor 100. The stator 102 is disposed so as to oppose the rotor 101. The housing 1 is a metallic casing that houses the rotor 101, the stator 102, and the like. The housing 1 holds the stator 102 and the bearings 5.

The heat sink 2 is formed using a material having good thermal conductivity such as aluminum, copper, or the like. In the present embodiment, the heat sink 2 is attached to the housing 1 by using screws 6. The circuit board 3 includes a control circuit of the motor 100. The circuit board 3 is disposed on a lower surface of the heat sink 2. The control circuit of the motor 100 is electrically connected to the stator 102 via a through hole provided in the housing 1 (an upper lid portion 1c to be described later).

On the lower surface of the circuit board 3, a position detection sensor 103 is provided. The center of the position detection sensor 103 is located on the rotation axis of the shaft 101a. The position detection sensor 103 detects the rotation angle of the rotor 101.

The bearings 5 are bearings that support the shaft 101a so as to be rotatable. The bearings 5 are constituted by, for example, ball bearings or sleeve bearings. The cover 104 is a member for protecting the circuit board 3.

The connector 105 is an external connection terminal. The connector 105 electrically connects the circuit board 3 to an external power supply (not illustrated) and other external devices (not illustrated) via wiring 105a. When power is supplied from the external power source to the stator 102 via the connector 105 and the circuit board 3, the rotor 101 can rotate relative to the stator 102.

The housing 1 has a cylindrical portion 1a, a lower lid portion 1b, the upper lid portion 1c, and a flange portion 1d. The lower lid portion 1b is formed of the same member as the cylindrical portion 1a and the flange portion 1d. The lower lid portion 1b covers the lower end surface of the cylindrical portion 1a. A central opening 10a is formed in a central portion of the lower lid portion 1b. One of the bearings 5 is attached to the central opening 10a, and the shaft 101a is inserted therein. Further, the present disclosure is not limited to the example illustrated in FIG. 1, and the cylindrical portion 1a, the lower lid portion 1b, and the flange portion 1d may be separate members.

The upper lid portion 1c is a holding portion that holds one of the bearings 5. The upper lid portion 1c covers the open-end surface of the cylindrical portion 1a on the upper side. The upper lid portion 1c is press-fitted onto the inner wall of the cylindrical portion 1a. That is, the upper lid portion 1c is press-fitted downward in the axial direction from the open-end surface of the upper side of the cylindrical portion 1a and is fixed to the cylindrical portion 1a. As a result, the upper lid portion 1c can be firmly fixed to the cylindrical portion 1a of the housing 1. Therefore, the upper lid portion 1c can stably hold the bearing 5, and the bearing 5 can stably support the shaft 101a so as to be rotatable.

The upper lid portion 1c has an annular portion 12, a protruding wall portion 13, and insertion holes 14a. A central opening 10b through which the shaft 101a is inserted is formed in the central portion of the annular portion 12. The protruding wall portion 13 is formed around the central opening 10b along the central opening 10b. The protruding wall portion 13 extends downward in the axial direction from the bottom surface of the annular portion 12. One of the bearings 5 is mounted inside the protruding wall portion 13. The bearing 5 is attached to the central opening 10b of the upper lid portion 1c. In addition, the other one of the bearings 5 is attached to the central opening 10a of the lower lid portion 1b. The bearing 5 attached to the central opening 10b of the upper lid portion 1c, together with the bearing 5 attached to the central opening 10a of the lower lid portion 1b, supports the shaft 101a so as to be rotatable.

The flange portion 1d has an annular shape. The flange portion 1d extends outward in the radial direction from the upper end of the cylindrical portion 1a. The plurality of insertion holes 14a are formed in the flange portion 1d along the outer periphery of the cylindrical portion 1a. The screws 6 are respectively inserted through the insertion holes 14a. Further, in FIG. 1, the screw 6 is used as a fixing member for fixing the heat sink 2 to the flange portion 1d. However, the present disclosure is not limited to this example, and the fixing member may be another member such as a rivet. In addition, the flange portion may have a plurality of portions extending outward in the radial direction from the upper end of the cylindrical portion 1a, and these portions may be arranged so as to be spaced apart from each other in the circumferential direction.

In addition, on the upper and lower surfaces of the flange portion 1d, polishing processing or the like may be performed around the insertion holes 14a. When such processing is performed, the surface roughness around the insertion holes 14a is made smaller than the surface roughness of other portions of the housing 1 (for example, the outer peripheral surface of the cylindrical portion 1a). In this case, the screws 6 and the heat sink 2 tend to come into close contact with the flange portion 1d. Therefore, the heat sink 2 can be more firmly attached and fixed to the flange portion 1d by using the screws 6.

As illustrated in FIG. 1, the heat sink 2 is in contact with the upper surface of the flange portion 1d. The heat sink 2 is attached to the flange portion 1d by using the screws 6. In the motor of the present embodiment, no other member such as a frame is interposed between the housing 1 and the heat sink 2. Therefore, in the motor of the present embodiment, the axial dimension can be made smaller than, for example, a motor with an existing structure with a frame interposed therebetween, and assembly can be easily performed. Furthermore, in the motor of the present embodiment, the number of components can be reduced and the manufacturing cost of the motor 100 can be reduced as compared with the motor with an existing structure as described above. In the present embodiment, the heat sink 2 is a single member. Further, it should be noted that the heat sink 2 is not limited to this example, and the heat sink 2 may be composed of a plurality of members.

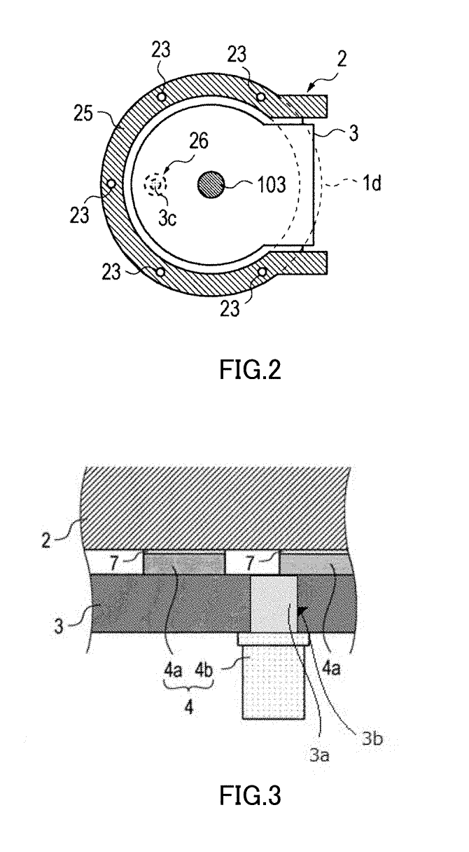

The heat sink 2 has screw holes 23, a protruding portion 25, a wiring path 26, and housing recesses 2a. The protruding portion 25 protrudes downward in the axial direction from the lower surface of the heat sink 2. The protruding portion 25 is attached to the upper surface of the flange portion 1d in the axial direction using the screws 6. FIG. 2 is a bottom view of the heat sink 2 according to the first embodiment of the present disclosure. FIG. 2 illustrates the lower surface of the heat sink 2 as viewed from below in the axial direction. In FIG. 2, broken lines indicate an inner peripheral edge and an outer peripheral edge of the upper surface of the flange portion 1d.

The protruding portion 25 is formed along the periphery of the lower surface of the heat sink 2 (refer to the left side of FIG. 2). However, the protruding portion 25 is not formed on a portion of the peripheral edge (refer to the right side of FIG. 2) on the lower surface of the heat sink 2. In this portion (that is, the portion where the protruding portion 25 is not formed), the heat sink 2 is not in contact with the upper surface of the flange portion 1d (refer to the right side of FIG. 1 and FIG. 2), and a portion of the circuit board 3 sticks out from between the heat sink 2 and the flange portion 1d. In addition, the connector 105 is connected to the circuit board 3 at this portion (that is, the portion where the protruding portion 25 is not formed).

The lower surface of the protruding portion 25 is in contact with the upper surface of the flange portion 1d. Therefore, it is possible to position the heat sink 2 in the axial direction with respect to the housing 1 by directly contacting the protruding portion 25 of the heat sink 2 to the flange portion 1d of the housing 1. Further, a portion of the lower surface of the protruding portion 25 is in contact with the upper surface of the annular portion 12 in FIG. 1. However, the present disclosure is not limited to this example, and a portion of the lower surface of the protruding portion 25 need not be in contact with the upper surface of the annular portion 12.

The screw holes 23 are provided on the lower surface of the protruding portion 25. When the heat sink 2 is attached to the flange portion 1d, the screws 6 are fixed in the screw holes 23 via the insertion holes 14a.

On the lower surface of the protruding portion 25, a portion in contact with the flange portion 1d is subjected to polishing processing or the like. The surface roughness of the lower surface of the protruding portion 25 subjected to the processing is smaller than the surface roughness of other surfaces (for example, the side surface) of the heat sink 2. As a result, when the flange portion 1d is screwed and fixed to the protruding portion 25 of the heat sink 2, the adhesion between the protruding portion 25 and the flange portion 1d is enhanced. Therefore, the heat sink 2 can be more firmly attached to the flange portion 1d by using the screws 6. Furthermore, because the adhesion between the protruding portion 25 and the flange portion 1d is increased, heat is more easily transmitted from the heat sink 2 to the housing 1, and the heat radiation performance of the heat sink 2 can be improved.

On the lower surface of the heat sink 2 and on the inner side of the protruding portion 25, the wiring path 26 and the housing recesses 2a are formed. The wiring path 26 is a through opening that penetrates the heat sink 2. The wiring path 26 is located on a terminal portion 3c (described later) provided on the upper surface of the circuit board 3. The wiring path 26 opens toward the terminal portion 3c. Wiring connected to the terminal portion 3c is drawn out to the outside through the wiring path 26. Accordingly, the terminal portion 3c is electrically connected to an external power source (not illustrated) via the wiring path 26. The upper end of the wiring path 26 is covered with the cover 104. As a result, it is possible to prevent dust and the like from entering the interior of the motor 100 through the wiring path 26. Further, note that the terminal portion 3c is not necessarily provided on the upper surface of the circuit board 3. The terminal portion 3c may be provided on the side surface of the circuit board 3. In addition, the terminal portion 3c may be provided on both the upper surface and side surface of the circuit board 3.

The housing recesses 2a house at least some of the electronic components 4 mounted on the circuit board 3. The housing recesses 2a are opposed to the electronic components 4 mounted on the upper surface of the circuit board 3 and are formed at positions corresponding thereto. The depth of the housing recesses 2a is set according to the dimension in the axial direction of the electronic components 4 to be housed therein.

The circuit board 3 is a substrate formed of a resin material such as epoxy, for example. The circuit board 3 is attached to the lower surface of the heat sink 2 using, for example, screws or rivets (not illustrated).

The electronic components 4 mounted on the circuit board 3 include a heat-generating element 4a having a relatively large amount of heat generation and low-heat-generating elements 4b having a relatively small amount of heat generation. The heat-generating element 4a is a switching element such as a field emission transistor (FET), for example. The low-heat-generating elements 4b are, for example, capacitors or the like. That is, the calorific value of the heat-generating element 4a is larger than the calorific value of the low-heat-generating elements 4b.

As illustrated in FIG. 1, the heat-generating element 4a is mounted on a surface of the circuit board 3 that is opposed to the heat sink 2 (that is, the upper surface of the circuit board 3). The heat-generating element 4a is housed in one of the housing recesses 2a between the heat sink 2 and the circuit board 3. Heat-dissipating grease 7 is applied to the upper surface of the heat-generating element 4a (for example, the surface that opposes the heat sink 2). In FIG. 1, the heat-generating element 4a is in contact with the bottom surface of the housing recesses 2a via the heat-dissipating grease 7. By transferring heat from the heat-generating element 4a to the heat sink 2 via the heat-dissipating grease 7, the heat generated by the heat-generating element 4a can be easily transmitted to the heat sink 2.

Some of the low-heat-generating elements 4b are mounted on the upper surface of the circuit board 3. The remaining ones of the low-heat-generating elements 4b are mounted on a surface of the circuit board 3 on the opposite side to the heat sink 2 (lower surface of the circuit board 3). Furthermore, the low-heat-generating elements 4b mounted on the upper surface of the circuit board 3 are housed in the housing recesses 2a between the heat sink 2 and the circuit board 3. The depth of the housing recesses 2a is a depth corresponding to the axial dimension of the low-heat-generating elements 4b. Therefore, even when the axial dimension of the low-heat-generating elements 4b is larger than the axial dimension of the heat-generating element 4a, the heat sink 2 and the heat-generating element 4a can be brought close to each other. Therefore, the heat sink 2 and the heat-generating element 4a can easily be brought into contact with each other through the heat-dissipating grease 7, heat generated by the heat-generating element 4a mounted on the circuit board 3 is easily transmitted to the heat sink 2, and temperature rise of the heat-generating element 4a can be suppressed.

Further, the present disclosure is not limited to the illustration in FIG. 1, a heat-dissipating agent other than the heat-dissipating grease 7, another heat-conducting member, or the like may be provided between the upper surface of the heat-generating element 4a and the bottom surface of the housing recess 2a. The heat-dissipating agent and the heat-conducting member may be provided instead of the heat-dissipating grease 7 as long as they are excellent in terms of thermal conductivity, electrical insulating property, and low thermal expansion, or may be provided together with the heat-dissipating grease 7. The heat-conducting member includes a metal member 3a penetrating the circuit board 3, and the heat-generating element 4a is mounted on a surface of the circuit board 3 on a side opposite to the heat sink 2.

Next, a modification example of the motor 100 according to the first embodiment will be described. FIG. 3 is a schematic longitudinal sectional view illustrating an example of a structure between the heat sink 2 and the circuit board 3 according to a modification example of the first embodiment. FIG. 3 illustrates a vertical cross section in the case where the heat sink 2 and the circuit board 3 are cut along a plane parallel to the axial direction.

Unlike the above-described structure illustrated in FIG. 1, in FIG. 3, the housing recesses 2a are not provided on the lower surface of the heat sink 2. As illustrated in FIG. 3, the heat-generating element 4a is disposed between the heat sink 2 and the circuit board 3. The heat-generating element 4a is in contact with the lower surface of the heat sink 2 via the heat-dissipating grease 7.

At least some of the electronic components 4 (for example, the low-heat-generating elements 4b) excluding the heat-generating element 4a are mounted on a surface of the circuit board 3 on the opposite side to the heat sink 2 (a lower surface of the circuit board 3). In this way, the electronic components 4, the axial dimension of which is larger than that of the heat-generating element 4a, are not disposed between the heat sink 2 and the circuit board 3. Therefore, the heat sink 2 and the heat-generating element 4a can easily be brought into contact with each other through the heat-dissipating grease 7. Therefore, the heat generated by the heat-generating element 4a mounted on the circuit board 3 is more likely to be transferred to the heat sink 2 and the temperature rise of the heat-generating element 4a can be suppressed.

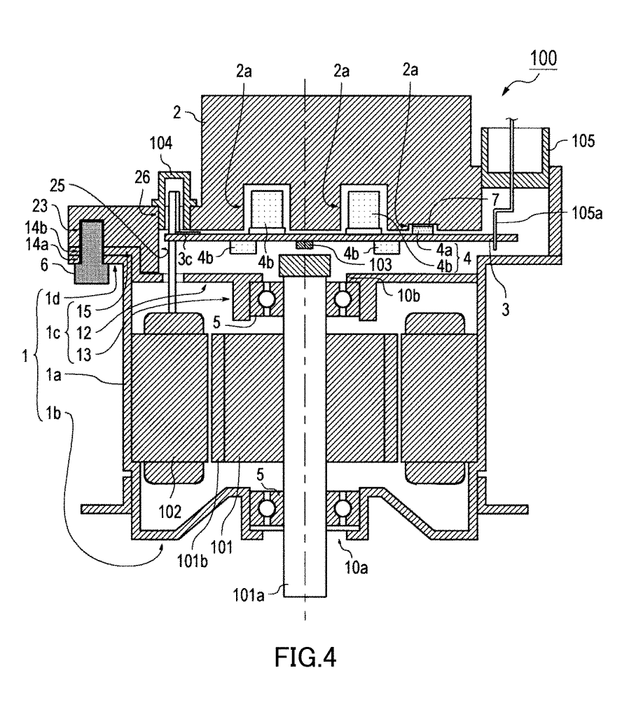

Next, the motor 100 according to a second exemplary embodiment of the present disclosure will be described. FIG. 4 is a schematic longitudinal sectional view illustrating an example of a structure of the motor 100 according to the second embodiment of the present disclosure. FIG. 4 illustrates a cross section in the case where the motor 100 is cut along a cutting plane including the rotation axis of the rotor 101. Further, the basic configuration of the present embodiment is the same as that of the first embodiment described above. Therefore, the same reference numerals and the same names are given to the constituent elements common to the first embodiment and explanation thereof may be omitted in some cases.

The upper lid portion 1c includes the annular portion 12, the protruding wall portion 13, the insertion holes 14a, and an extension portion 15. The extension portion 15 extends outward in the radial direction from the upper end of the annular portion 12 and is disposed between the flange portion 1d and the protruding portion 25 of the heat sink 2.

Along the outer periphery of the cylindrical portion 1a, a plurality of insertion holes 14b are formed in the extension portion 15. When the protruding portion 25 of the heat sink 2 is attached to the flange portion 1d using the screws 6, the screws 6 are inserted through the insertion holes 14a of the flange portion 1d and the insertion holes 14b of the extension portion 15 and fixed in the screw holes 23. Therefore, the protruding portion 25 of the heat sink 2 is fixed to the flange portion 1d by the screws 6 with the extension portion 15 interposed therebetween.

Thus, the extension portion 15 is fixed between the protruding portion 25 of the heat sink 2 and the flange portion 1d using the screws 6, and the upper lid portion 1c can be firmly fixed to the housing 1 and the heat sink 2. Therefore, the upper lid portion 1c can stably hold the bearing 5, and the bearing 5 can stably support the shaft 101a so as to be rotatable.

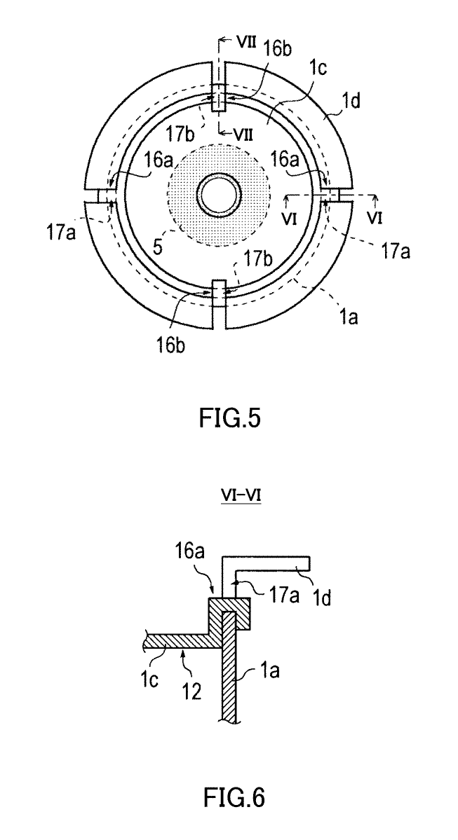

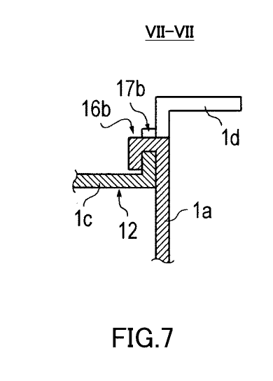

Next, the motor 100 according to a third exemplary embodiment of the present disclosure will be described. FIG. 5 is a top view of the housing 1 according to the third embodiment of the present disclosure. FIG. 6 is a cross-sectional view illustrating an example of a structure for fixing the upper lid portion 1c to the cylindrical portion 1a in the third embodiment of the present disclosure. FIG. 7 is a cross-sectional view illustrating another example of a structure for fixing the upper lid portion 1c to the cylindrical portion 1a in the third embodiment of the present disclosure. FIG. 5 illustrates the upper surface of the housing 1 as viewed from above in the axial direction. FIG. 6 illustrates a partial longitudinal section of the housing 1 taken along a dashed line VI-VI in FIG. 5. FIG. 7 illustrates a partial longitudinal section of the housing 1 taken along a one-dot chain line VII-VII in FIG. 5. Further, the basic configuration of the present embodiment is the same as that of the first embodiment described above. Therefore, the same reference numerals and the same names are given to the constituent elements common to the first embodiment, and explanation thereof may be omitted in some cases.

The cylindrical portion 1a has projecting portions 16b and fitting portions 17a. The projecting portions 16b protrude in the radial direction from the inner surface of the cylindrical portion 1a. The fitting portions 17a are recessed portions. The projecting portions 16b and the fitting portions 17a are formed in the cylindrical portion 1a along the circumferential direction. Further, the fitting portions 17a are not limited to the example illustrated in FIG. 5 and FIG. 6, and may be through holes. In addition, the number of the projecting portions 16b and the number of the fitting portions 17a provided in the cylindrical portion 1a may be each any natural number of 1 or more.

The upper lid portion 1c has projecting portions 16a and fitting portions 17b. The projecting portions 16b protrude in the radial direction from the outer surface of the upper lid portion 1c. The fitting portions 17b are recessed portions. The projecting portions 16a and the fitting portions 17b are formed along the circumferential direction at the outer peripheral edge of the upper lid portion 1c. Further, it should be noted that the fitting portions 17b are not limited to the example illustrated in FIG. 5 and FIG. 7, and may be through holes. In addition, the number of the projecting portions 16a and the number of the fitting portions 17b provided in the upper lid portion 1c may be each a natural number of 1 or more.

When the upper lid portion 1c is attached to the cylindrical portion 1a, as illustrated in FIG. 6, the projecting portions 16a of the upper lid portion 1c are fitted to the fitting portions 17a of the cylindrical portion 1a, and the projecting portions 16a and the fitting portions 17a are caulked and fixed. Furthermore, as illustrated in FIG. 7, the projecting portions 16b of the cylindrical portion 1a are fitted to the fitting portions 17b of the upper lid portion 1c, and the projecting portions 16b and the fitting portions 17b are caulked and fixed.

In this way, by using the caulking fixing structure of the projecting portions 16a and the fitting portions 17a and the caulking fixing structure of the projecting portions 16b and the fitting portions 17b, the upper lid portion 1c that holds the bearing 5 is firmly fixed to the cylindrical portion 1a. Therefore, the upper lid portion 1c can stably hold the bearing 5, and the bearing 5 can stably support the shaft 101a so as to be rotatable.

Further, note that the present disclosure is not limited to the examples in FIG. 5 to FIG. 7, and the projecting portions 16a and 16b may protrude in the axial direction. In addition, the cylindrical portion 1a may have one of projecting portions and fitting portions, and the upper lid portion 1c may have the other of the projecting portions and the fitted portions. That is, the cylindrical portion 1a may have the fitting portions 17a and the upper lid portion 1c may have the projecting portions 16a. Alternatively, the cylindrical portion 1a may have the projecting portions 16b and the upper lid portion 1c may have the fitting portions 17b. Even with these configurations, the projecting portions 16a and the fitting portions 17a can be caulked and fixed, and the projecting portions 16b and the fitting portions 17b can be caulked and fixed. As a result, the upper lid portion 1c can stably hold the bearing 5, and the bearing 5 can stably support the shaft 101a so as to be rotatable.

For example, in the above-described first to third embodiments, the case where the motor of the present disclosure is applied to an in-vehicle motor has been illustrated; however, the motor of the present disclosure may be applied to a motor other than an in-vehicle motor.

The motor of the present disclosure can be used for, for example, an in-vehicle motor, and can also be used for a motor for other purposes.

Features of the above-described embodiments and the modifications thereof may be combined appropriately as long as no conflict arises.

While embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

1. A motor comprising:
a rotor comprising a rotating shaft extending in an up-down direction;
a stator opposing the rotor;
a housing holding the stator;
a heat sink attached to the housing; and
a circuit board on which electronic components are mounted and which is disposed on a lower surface of the heat sink,
wherein the electronic components comprise a heat-generating element,
wherein the housing comprises a cylindrical portion and a flange portion extending outward in a radial direction from an upper end of the cylindrical portion, and
wherein the heat sink comprises a protruding portion protruding downward in an axial direction and is attached to an upper surface of the flange portion in the axial direction using a fixing member, and
wherein the heat-generating element is in contact with the heat sink via a heat-conducting member.

2. The motor according to claim 1,
wherein the fixing member is a screw or a rivet.

3. The motor according to claim 2,
wherein the flange portion comprises an insertion hole,
wherein the fixing member is inserted through the insertion hole, and
wherein surface roughness around the insertion hole in the flange portion is less than surface roughness of an outer peripheral surface of the cylindrical portion.

4. The motor according to claim 1, wherein the heat sink is in contact with the flange portion.

5. The motor according to claim 2, further comprising:
a bearing supporting the rotating shaft; and
a holding portion holding the bearing,
wherein the holding portion comprises an extension portion extending outward in the radial direction from the upper end, and
wherein the protruding portion is fixed to the flange portion by the fixing member with the extension portion interposed therebetween.

6. The motor according to claim 1, further comprising:
a bearing supporting the rotating shaft; and
a holding portion holding the bearing,
wherein the holding portion is press-fitted onto an inner wall of the cylindrical portion.

7. The motor according to claim 1, further comprising:
a bearing supporting the rotating shaft; and
a holding portion holding the bearing,
wherein the holding portion has a first projecting portion,
wherein the first projecting portion protrudes in the radial direction or the axial direction from an outer surface of the holding portion,
wherein the housing comprises a first fitting portion,
wherein the first fitting portion is a recessed portion or a through hole to be fitted to the first projecting portion, and
wherein the first projecting portion and the first fitting portion are caulked and fixed.

8. The motor according to claim 7,
wherein the housing has a second projecting portion,
wherein the second projecting portion protrudes in the radial direction or the axial direction,
wherein the holding portion comprises a second fitting portion,
wherein the second fitting portion is a recessed portion or a through hole to be fitted to the second projecting portion, and
wherein the second projecting portion and the second fitting portion are caulked and fixed.

9. The motor according to claim 1, further comprising:
a bearing supporting the rotating shaft; and
a holding portion holding the bearing,
wherein the housing comprising a projecting portion,
wherein the projecting portion protrudes in the radial direction or the axial direction from an inner surface of the housing,
wherein the holding portion comprises a fitting portion,
wherein the fitting portion is a recessed portion or a through hole to be fitted to the projecting portion, and
wherein the projecting portion and the fitting portion are caulked and fixed.

10. The motor according to claim 1,
wherein a terminal portion to be externally connected is provided on at least one of an upper surface and a side surface of the circuit board,
wherein the heat sink comprises a through opening penetrating the heat sink, and
wherein the through opening is located above the terminal portion.

11. The motor according to claim 1,
wherein the heat-generating element is disposed between the heat sink and the circuit board.

12. The motor according to claim 11,
wherein at least some of the electronic components excluding the heat-generating element are mounted on a surface of the circuit board on a side opposite to the heat sink.

13. The motor according to claim 1,
wherein the heat-conducting member comprises a metal member penetrating the circuit board, and
wherein the heat-generating element is mounted on a surface of the circuit board on a side opposite to the heat sink.

14. The motor according to claim 1,
wherein the heat-conducting member comprises heat-dissipating grease.

15. The motor according to claim 1,
wherein the heat-generating element is a switching element.
